(19) United States
(12) Patent Application Publication
(10) Pub. No.: US 2018/0156604 A1
(43) Pub. Date: Jun. 7, 2018

(54) POLISHING METHOD AND POLISHING APPARATUS

(71) Applicant: SAMSUNG ELECTRONICS CO., LTD., Suwon-si (KR)

(72) Inventor: Dong-Min SEO, Hwaseong-si (KR)

(21) Appl. No.: 15/649,983

(22) Filed: Jul. 14, 2017

(30) Foreign Application Priority Data
Dec. 6, 2016 (KR) 10-2016-0165097

(51) Int. Cl. G01B 11/06; G01N 21/55; B24B 49/12; H01L 21/66

(52) U.S. Cl. CPC G01B 11/0633; H01L 22/12; B24B 49/12; G01N 21/55

(57) ABSTRACT

In a polishing method, a substrate having a layer formed thereon is polished. A measurement spectrum is obtained by detecting light reflected from the polished surface of the substrate. A skew spectrum between a golden spectrum for a target thickness and the measurement spectrum is obtained. A Fourier transform operation is performed on the skew spectrum to calculate a thickness of the layer.

### CROSS-REFERENCE TO RELATED APPLICATION

Korean Patent Application No. 10-2016-0165097, filed on Dec. 6, 2016, in the Korean Intellectual Property Office, and entitled: “Polishing Method and Polishing Apparatus,” is incorporated by reference herein in its entirety.

### BACKGROUND

### 1. Field

Example embodiments relate to a method and an apparatus for polishing a substrate having a layer formed thereon. More particularly, example embodiments relate to a polishing method capable of detecting a polishing end point based on an optical information included in light reflected from a substrate and a polishing apparatus for performing the same.

### 2. Description of the Related Art

Semiconductor devices may be fabricated through several processes including a process of polishing an insulation layer, e.g., SiO₂, and a processing polishing a metal layer, e.g., copper, tungsten, etc. Polishing of a wafer may be terminated when a thickness of a target layer (for example, the insulation layer, the metal layer or the silicon layer) has reached a target thickness. For example, a chemical mechanical polishing (CMP) apparatus may be used for polishing the wafer.

In the CMP process, a polishing operation may be stopped when an underlying layer is exposed. In this case, a reflectivity between the underlying layer and an upper layer, eddy current, motor torque of the CMP apparatus may be detected to determine a polishing end point. Alternatively, the polishing process may need to be terminated so as to leave the upper layer with a predetermined thickness. Thus, in case of a process that removes layers equally during polishing, e.g., P3 process (buffing process) of CMP process, the polishing end point may be determined merely as a function of polishing thereby leading to within-wafer non-uniformity and wafer-to-wafer non-uniformity.

### SUMMARY

According to example embodiments, in a polishing method, a substrate having a layer formed thereon is polished to form a polished surface. A measurement spectrum is obtained by detecting light reflected from the polished surface of the substrate. A skew spectrum between a golden spectrum for a target thickness and the measurement spectrum is obtained. A Fourier transform operation is performed on the skew spectrum to calculate a thickness of the layer.

According to example embodiments, in a polishing method, a golden spectrum is obtained from a surface of a substrate having a layer with a target thickness. A substrate having a layer formed thereon is polished to form a polished surface. A measurement spectrum is obtained by detecting light reflected from the polished surface of the substrate. A skew spectrum between the golden spectrum and the measurement spectrum is obtained. A Fourier transform operation is performed on the skew spectrum to calculate a thickness of the layer.

According to example embodiments, a polishing apparatus includes a rotatable polishing table with a polishing pad, a carrier head to hold and press a substrate having layer formed thereon against the polishing pad on the rotating polishing pad, a light irradiator configured to irradiate light the substrate held by the carrier head, a light detector to detect the light reflected from the substrate to obtain a measurement and a data processor connected to the light detector. The data processor includes a spectrum calculator for obtaining a skew spectrum between the measurement spectrum and a golden spectrum for a target thickness, a Fourier transform operator for obtaining Fourier transform spectrum from the obtained skew spectrum by a Fourier transform, a thickness calculator for calculating a thickness of the layer based on the Fourier transform spectrum.

According to example embodiments, a method of manufacturing a substrate includes fouling a layer on the substrate and polishing a first surface of the layer on the substrate. Polishing the layer on the substrate includes obtaining a measurement spectrum by detecting light reflected from the first surface of the layer, obtaining a skew spectrum between a golden spectrum for a target thickness and the measurement spectrum, and performing a Fourier transform operation on the skew spectrum to calculate a thickness of the layer.

### BRIEF DESCRIPTION OF THE DRAWINGS

Features will become apparent to those of skill in the art by describing in detail exemplary embodiments with reference to the attached drawings in which:

FIG. 1 illustrates a perspective view of a chemical mechanical polishing apparatus in accordance with example embodiments.

FIG. 2 illustrates a cross-sectional view of the chemical mechanical polishing apparatus in FIG. 1.

FIG. 3 illustrates a block diagram of an optical monitoring device of the chemical mechanical polishing apparatus in FIG. 1.

FIG. 4 illustrates a plan view of a positional relationship between a wafer and a polishing table of the chemical mechanical polishing apparatus in FIG. 1.

FIG. 5 illustrates graphs of measurement spectrums in detection positions in FIG. 4.

FIG. 6 illustrates a flow chart of a polishing method in accordance with example embodiments.

FIG. 7 illustrates a view of layers formed on a wafer in a polishing process.

FIG. 8 illustrates graphs of skew spectrums obtained from a surface of the wafer in FIG. 7 by an optical monitoring device.

FIG. 9 illustrates graphs of Fourier transform spectrums of the skew spectrums in FIG. 8.

### DETAILED DESCRIPTION

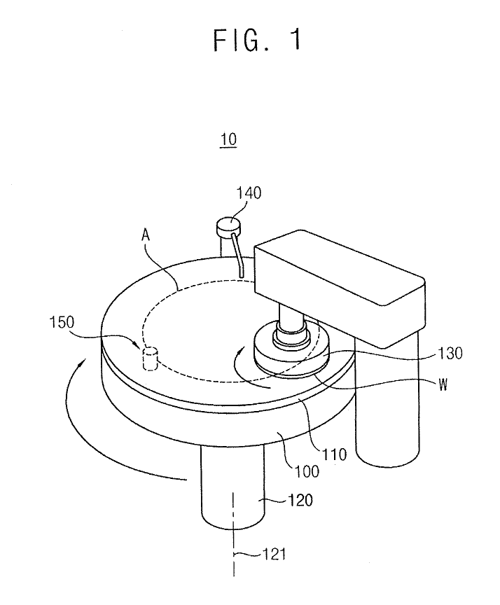

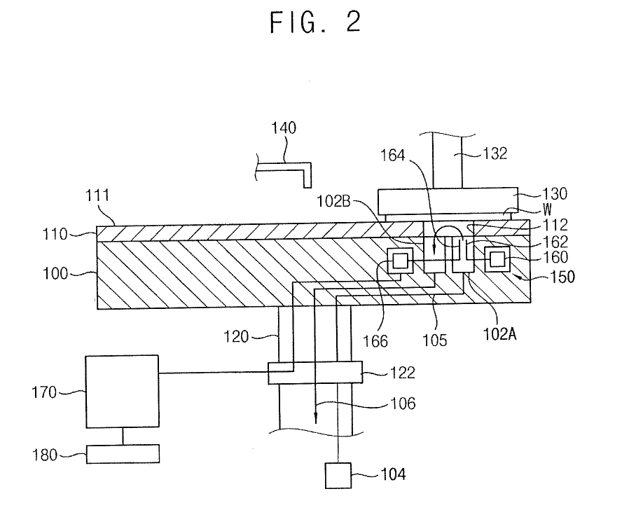

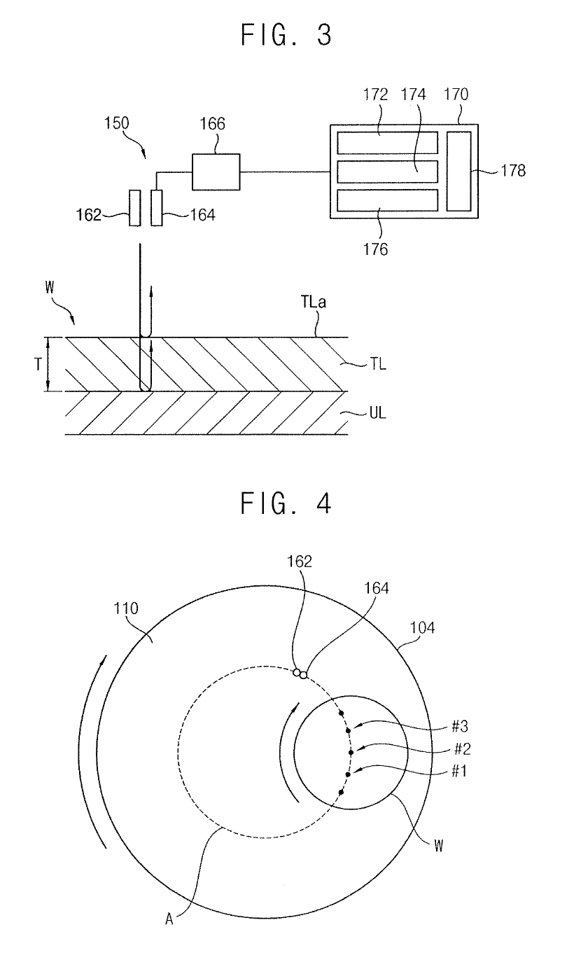

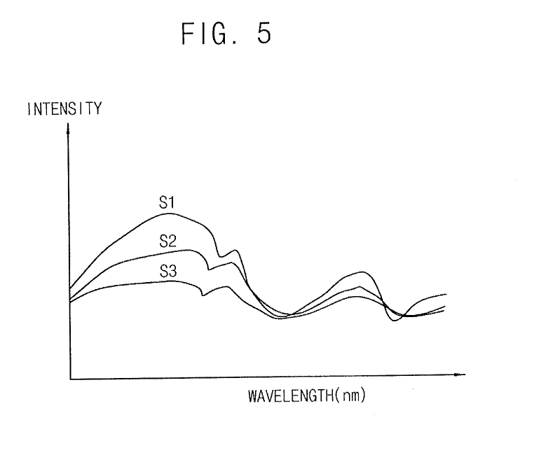

FIG. 1 is a perspective view illustrating a chemical mechanical polishing apparatus in accordance with example embodiments. FIG. 2 is a cross-sectional view illustrating the chemical mechanical polishing apparatus in FIG. 1. FIG. 3 is a block diagram illustrating an optical monitoring device of the chemical mechanical polishing apparatus in FIG. 1. FIG. 4 is a plan view illustrating a positional relationship between a wafer and a polishing table of the chemical mechanical polishing apparatus in FIG. 1. FIG. 5 are graphs illustrating measurement spectrums in detection positions in FIG. 4.

Referring to FIGS. 1 to 5, a chemical mechanical polishing (CMP) apparatus 10 may include a polishing table 100 with a polishing pad 110 attached to an upper surface thereof, a carrier head 130 to hold and press a substrate, e.g., a wafer W, against the polishing pad 110, a slurry supply device 140 to supply a polishing liquid (slurry) onto the polishing pad 110 during a CMP process, and an in-situ optical monitoring device configured to measure a thickness of a layer during polishing of the wafer W.

The wafer may be a substrate formed of a semiconductor or non-semiconductor material. The wafer may include one or more layers formed on the substrate. For example, such layers may include, but are not limited to, a resist, a dielectric material or a conductive material. Additionally, the wafer may include a plurality of dies, each having repeatable pattern features.

The polishing table 100 may have a rotatable disk-shaped platen on which the polishing pad 110 is situated. The polishing pad 110 may rotate about an axis 121. For example, a motor may turn a drive shaft 120 to rotate the polishing pad 110.

The carrier head 130 may include a retaining ring to retain the wafer W below a flexible membrane. The membrane may form a plurality of independently controllable pressurizable chambers. The carrier head 130 may be suspended from a support structure, and may be connected to a drive shaft to rotate about its central axis. The carrier head may be translated laterally across a top surface of the polishing pad 110.

Thus, as may be seen in FIGS. 1 and 4, both the polishing pad 110 and the carrier head 130 are rotated, and the carrier head may be translated around a perimeter of an area A of the polishing pad 110.

The carrier head 130 and the polishing table 100 may rotate as indicated by arrows. In this state, the carrier head 130 may press the wafer W against the polishing pad 110, while the slurry supply device 140 may supply the polishing liquid onto the polishing pad 110. The wafer W may be polished by sliding contact with the polishing pad 110 in the presence of the polishing liquid.

The in-situ optical monitoring device 150 may be used to monitor the progress of the polishing process, adjust a polishing rate, and detect a polishing end point. The optical monitoring device 150 may include a light irradiator, a light detector, and a data processor 170.

In particular, the light irradiator may include a light source 160 and a first optical fiber 162 for directing light, emitted from the light source 160, to a surface of the wafer W to be polished. The light detector may include a second light fiber 164 for receiving the light reflected from the wafer W and a spectroscope 166 to detect the reflected light and measure an intensity of the reflected light over a predetermined wavelength range. The spectroscope 166 may produce a spectrum that represents intensities of the light at the respective wavelengths with the wavelength range. The data processor 170 may be connected to the spectroscope 166, and may calculate a thickness of a target layer on the surface of the wafer W based on the light intensity data (spectrum) obtained from the spectroscope 166.

As illustrated in FIG. 2, a first hole 102A and a second hole 102B may be in an upper surface of the polishing table 100, and a through hole 112 may be formed in the polishing pad 110 to be connected to the first and second holes 102A, 102B, e.g., have edges that align with outer edges of the first and second holes 102A, 102B. The through hole 112 may have an upper open end in a polishing surface 111. The first 102A may be coupled to a liquid supply source 104 via a liquid supply passage 105 and rotary joint 122. The second hole 102B may be coupled to a liquid discharge passage

During polishing of the wafer W, the liquid supply source 104 may supply a transparent liquid, e.g., water, into the first hole 102A and the through hole 112 via the liquid supply passage 105, to fill a space between the polished surface of the wafer W and tip ends of the first and second optical fibers 162 and 164. The wafer may further flow into the second hole 102B, as indicated by the curved arrow between the first and second holes 102A, 102B, and then may be discharged through the liquid discharge passage 106. The polishing liquid may be discharged together with the water and a path of light may be secured.

The tip ends of the first and second light fibers 162 and 164 may be arranged in the first hole 102A, and may be located near the polished surface of the wafer W, e.g., may extend towards the through hole 112. The tip ends of the first and second optical fibers 162 and 164 may be oriented toward the center of the wafer W held by the carrier head 130, so that multiple regions including the center of the wafer W are irradiated with light each time the polishing table 100 makes one revolution.

The light source 160 may include a light emitting diode (LED), a halogen lamp, a xenon lamp, or the like. The tip ends of the first and second light fibers 162 and 164 may be substantially perpendicular to the surface of the wafer W, so that the light may be directed to the surface of the wafer W perpendicularly.

Alternatively, instead of the liquid supply passage, the liquid discharge passage, and the liquid supply source, a transparent window may be provided in the polishing pad 110. In this case, the first optical fiber of the light irradiator may irradiate light onto the surface of the wafer W through the transparent widow, and the second optical fiber may receive the light reflected from the wafer W through the transparent window.

As illustrated in FIGS. 3 and 4, the polished wafer W may include a lower layer UL and an upper layer TL formed on the lower layer UL. An upper surface TLa of the upper layer TL of the wafer W may be pressed against the polishing pad 110. The upper surface TLa of the wafer W may be polished by sliding contact with the polishing pad 110. While the polishing table 100 is making one revolution, a plurality of detection regions #1, #2, #3 including the center of the wafer W may be irradiated with light. The light reflected from the surface TLa of the wafer W may be received in the second light fiber 164. The spectroscope 166 coupled to the second light fiber 164 may resolve the reflected light according to the wavelength and measure intensities of the reflected light over a predetermined wavelength range. The spectroscope 166 may produce a spectrum that represents intensities of the light at the respective wavelengths.

Alternatively, the spectroscope 166 may provide light intensity data of the light measured over the predetermined wavelength range with the data processor 170, and the data processor 170 may produce the spectrum that represents intensities of the light at the respective wavelengths, from the light intensity data obtained by the spectroscope 166.

As illustrated in FIG. 5, during one revolution of the polishing table 100, measurement spectrums S1, S2, and S3 may be obtained in the detection regions #1, #2 and #3 respectively. The first position spectrum Si may be a spectrum obtained from the light reflected in the first detection site #1, the second position spectrum S2 may be a spectrum obtained from the light reflected in the second detection site #2, and the third position spectrum S3 may be a spectrum obtained from the light reflected in the third detection site #3. The number of measuring operations conducted during one revolution of the polishing table 100 may not be limited thereto, and may be determined by the rotational speed of the polishing table 100, a rotational speed of the carrier head 130, etc.

The light intensity of the reflected light in the measurement spectrums may vary according to a thickness T of the upper or target layer TL. The light intensity of the reflected light in the measurement spectrums may vary according a pattern density of the lower layer UL under the target layer TL. That is, some of the measurement spectrums obtained during one revolution of the polishing pad 110 may not represent the layer thickness accurately. This is because the spectrums obtained during the sweep across the wafer may be obtained from the light reflected from a cell region or a circuit region within the die.

In example embodiments, the data processor 170 may select one of the measurement spectrums obtained during one revolution of the polishing table 100 that is capable of representing a thickness of the target layer accurately. For example, one optimal spectrum of the first to third position spectrums S1, S2, and S3, that represents the layer thickness accurately, e.g., a median spectrum, may be selected. For example, the selected spectrum may be considered as the spectrum which is obtained from the light reflected from a desired region (cell region or circuit region). Accordingly, the selected spectrum may represent the layer thickness in a specific polishing step accurately without being affected by the pattern density of the underlying layer.

In example embodiments, the data processor 170 may include a skew spectrum calculator 172 for obtaining a skew spectrum between a measurement spectrum obtained during one revolution of the polishing table 100 and a golden spectrum for a target thickness of the upper layer TL, a Fourier transform operator 174 for obtaining a Fourier transform spectrum from the obtained skew spectrum by a Fourier transform, and a thickness calculator 176 for calculating a thickness of the upper layer TL based on the Fourier transform spectrum and determining a polishing end point.

The data processor 170 may further include a memory 178 for storing the golden spectrum. The golden spectrum may be a standard spectrum obtained a surface of a substrate on which a layer having a target thickness is formed. The golden spectrum may be obtained using an optical measuring instrument such as the spectroscope 166 or a spectroscopic ellipsometry.

The optical monitoring device 150 may include a controller 180 which controls a polishing rate based on the layer thickness calculated by the data process 170 and a polishing operation on the wafer W according to the determined polishing end point detection signal.

Hereinafter, a method of polishing a wafer using the polishing apparatus will be explained.

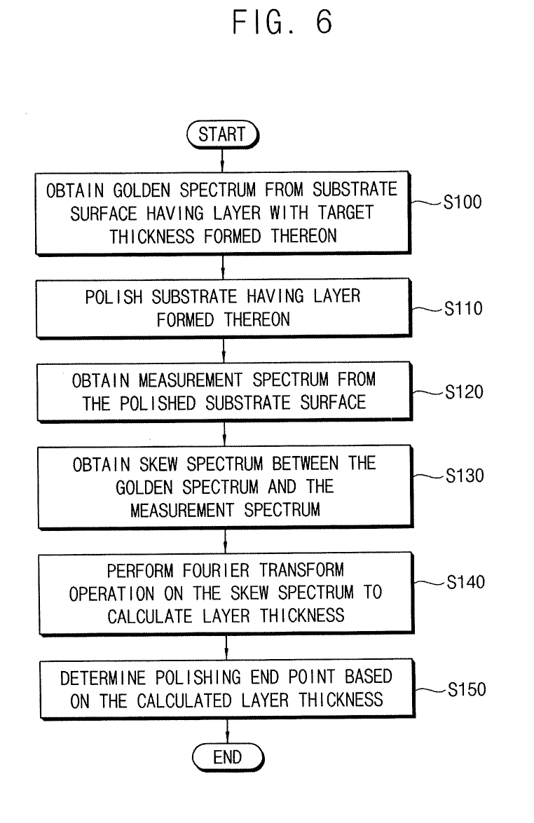

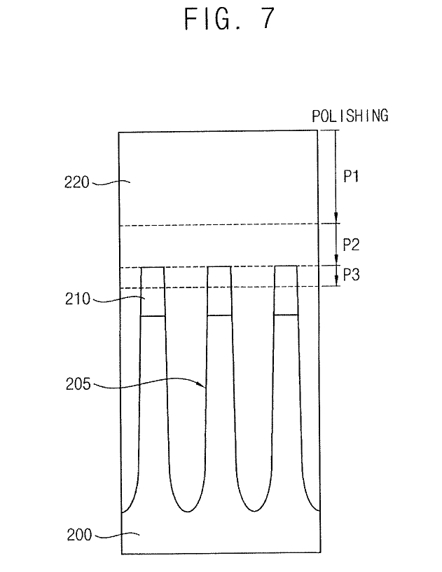

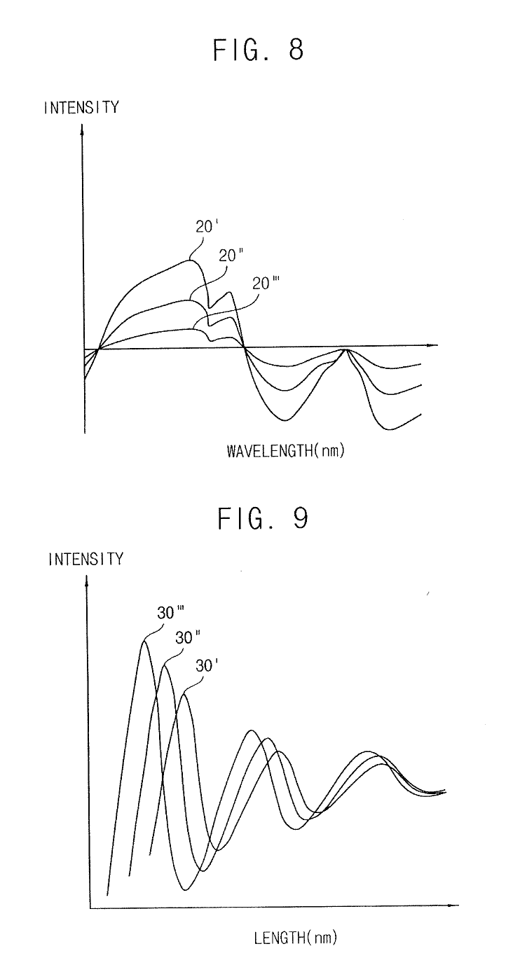

FIG. 6 is a flow chart illustrating a polishing method in accordance with example embodiments. FIG. 7 is a view illustrating layers formed on a wafer in a polishing process. FIG. 8 are graphs illustrating skew spectrums obtained from a surface of the wafer in FIG. 7 by an optical monitoring device. FIG. 9 are graphs illustrating Fourier transform spectrums of the skew spectrums in FIG. 8.

Referring to FIGS. 6 to 7, in example embodiments, a polishing end point of a polishing process on an oxide layer 220 formed on a silicon substrate 200 may be determined using an optical monitoring device 150 in FIG. 2.

In particular, after a hard mask 210 is formed on a substrate 200, the substrate 200 may be etched using the hard mask 210 as an etching mask to form a trench 205. For example, the substrate may include a silicon substrate. The substrate 200 may be a silicon substrate, a germanium substrate, a silicon-germanium substrate, a silicon-on-insulator (SOI) substrate, a germanium-on-insulator (GOI) substrate, etc. The hard mask 210 may be formed to include a nitride, e.g., silicon nitride.

Then, an oxide layer 220 may be formed as an isolation layer on the substrate 200 to sufficiently fill the trench 205 and an upper portion of the oxide layer 220 may be polished using a polishing apparatus 10 in FIG. 1 until the oxide layer 220 in the trench 205 has a target thickness, to form an isolation layer pattern in the trench 205. The oxide layer 220 may be formed to include an oxide, e.g., silicon oxide.

The polishing may include a first polishing process P1, a second polishing process P2, and a third polishing process P3. The first polishing process P1 may be performed in a relatively rapid speed within a predetermined process time. An end point of the second polishing process P2 may be determined by detecting a change of a motor torque or a change of reflectivity, e.g., as the hard mask 210 is exposed. An end point of the third polishing process P3, which is a buffing process that affects all materials equally, may be determined using a data processor 170 as described later, to terminate the third polishing process P3.

First, after a gold spectrum for a layer having a target thickness is obtained (S100), a surface of a substrate may be polished, and a measurement spectrum may be obtained from the substrate surface (S110, S120).

In particular, before performing a polishing process, after a golden spectrum Sg is obtained from the oxide layer 220 having a target thickness using an optical measuring instrument, e.g., a spectroscope 166 or a spectroscopic ellipsometry, during a first one revolution of the polishing table 100 in the third polishing process P3, a first measurement spectrum S′ may be obtained from the polished surface of the substrate. The first measurement spectrum S′ may be a spectrum selected from a plurality of measurement spectrums obtained during the first one revolution of the polishing table 100 that represents a thickness of the oxide layer 220 accurately.

Referring to FIG. 8, a first skew spectrum 20′ between the golden spectrum Sg and the first measurement spectrum S′ may be obtained (S120). The first skew spectrum 20′ may be a difference spectrum between the golden spectrum Sg and the first measurement spectrum S′ obtained during the first measuring operation.

Referring to FIG. 9, after a Fourier transform operation is performed on the first skew spectrum 20′ to calculate a thickness of the oxide layer 220 (S140), a polishing end point may be determined based on the calculated thickness (S150). For example, a fast Fourier transform (FFT) operation may be performed on the first skew spectrum 20′ to obtain a first Fourier transform spectrum 30′, and a peak of the first Fourier transform spectrum 30′ may be analyzed to determine the thickness of the oxide layer 220.

The first Fourier transform spectrum 30′ may be a fast Fourier transform (FFT) spectrum of the first skew spectrum 20′. A first peak value of Y axis may be analyzed to determine the thickness of the oxide layer 220. Accordingly, the thickness of the layer 220 may be calculated based on a specific peak position (X axis peak value or Y axis peak value).

When the calculated thickness of the layer 220 is not equal to a target thickness or within a permissible range, processes S110 to S150 may be performed repeatedly as described below.

During a second one revolution of the polishing table 100, a second measurement spectrum S″ may be obtained from the polished surface of the substrate. The second measurement spectrum S″ may be a spectrum selected from a plurality of measurement spectrums obtained during the second one revolution of the polishing table 100, which is capable of representing a thickness of the oxide layer 220 accurately.

Then, after a second skew spectrum 20″ between the golden spectrum Sg and the second measurement spectrum S″ is obtained, and a Fourier transform operation may be performed on the second skew spectrum 20″ to calculate a thickness of the oxide layer 220. For example, a fast Fourier transform (FFT) operation may be performed on the second skew spectrum 20″ to obtain a second Fourier transform spectrum 30″, and a peak of the second Fourier transform spectrum 30″ may be analyzed to determine the thickness of the oxide layer 220.

The second Fourier transform spectrum 30″ may be a fast Fourier transform (FFT) spectrum of the second skew spectrum 20″. A first peak value of Y axis may be analyzed to determine the thickness of the oxide layer 220. Accordingly, the thickness of the layer 220 may be calculated based on a specific peak position (X axis peak value or Y axis peak value).

Then, a polishing end point may be determined based on the calculated thickness. When it is determined that the calculated thickness of the layer 220 is not equal to a target thickness or within a permissible range, processes S110 to S150 may be performed repeatedly as described below.

During a third one revolution of the polishing table 100, a third measurement spectrum S′″ may be obtained from the polished surface of the substrate. The third measurement spectrum S′″ may be a spectrum selected from a plurality of measurement spectrums obtained during the third one revolution of the polishing table 100, which is capable of representing a thickness of the oxide layer 220 accurately.

Then, after a third skew spectrum 20′″ between the golden spectrum Sg and the third measurement spectrum S′″ is obtained, a Fourier transform operation may be performed on the third skew spectrum 20′″ to calculate a thickness of the oxide layer 220.

For example, a fast Fourier transform (FFT) operation may be performed on the third skew spectrum 20′″ to obtain a third Fourier transform spectrum 30′″, and a peak of the third Fourier transform spectrum 30′″ may be analyzed to determine the thickness of the oxide layer 220.

The third Fourier transform spectrum 30′″ may be a fast Fourier transform (FFT) spectrum of the third skew spectrum 20′″. A first peak value of Y axis may be analyzed to determine the thickness of the oxide layer 220. Accordingly, the thickness of the layer 220 may be calculated based on a specific peak position (X axis peak value or Y axis peak value).

Then, a polishing end point may be determined based on the calculated thickness. When it is determined that the calculated thickness of the layer 220 is equal to a target thickness or within a permissible range, a polishing end point detection signal may be generated and the controller 180 may control to terminate the polishing operation on the substrate according to the determined polishing end point detection signal.

By way of summation and review, in the polishing apparatus and the polishing method according to embodiments, the skew spectrum between the spectrum obtained from the polished surface of the substrate during polishing of the substrate and the golden spectrum obtained from the layer having the target thickness may be calculated, and a Fourier transform operation may be performed on the skew spectrum, to remove noise and obtain a desired thickness component, to thereby calculate a thickness of the layer to be polished accurately. Accordingly, the polishing end point of the substrate may be determined accurately based on the calculated thickness.

The above polishing apparatus and polishing method may be applied to a manufacture of various semiconductor devices. For example, the semiconductor device may be applied to a wiring structure included in logic devices such as central processing units (CPUs), main processing units (MPUs), or application processors (APs), or the like, and volatile memory devices such as DRAM devices or SRAM devices, or non-volatile memory devices such as flash memory devices, PRAM devices, MRAM devices, ReRAM devices, or the like.

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form the basis of the methods (or operations of the computer, processor, controller, or other signal processing device) are described in detail, the code or instructions for implementing the operations of the method embodiments may transform the computer, processor, controller, or other signal processing device into a special-purpose processor for performing the methods described herein.

Also, another embodiment may include a computer-readable medium, e.g., a non-transitory computer-readable medium, for storing the code or instructions described above. The computer-readable medium may be a volatile or non-volatile memory or other storage device, which may be removably or fixedly coupled to the computer, processor, or controller which is to execute the code or instructions for performing the method embodiments described herein.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A polishing method, comprising:
polishing a layer on a substrate to form a polished surface;
obtaining a measurement spectrum by detecting light reflected from the polished surface of the substrate;
obtaining a skew spectrum between a golden spectrum for a target thickness and the measurement spectrum; and
performing a Fourier transform operation on the skew spectrum to calculate a thickness of the layer.

2. The polishing method as claimed in claim 1, wherein obtaining the measurement spectrum includes:
detecting light reflected from the polished surface of the substrate during each revolution of a polishing table supporting the substrate; and
producing the measurement spectrum from the detected light.

3. The polishing method as claimed in claim 1, wherein obtaining the measurement spectrum includes:
detecting light in a plurality of detection regions including a center of the substrate during each revolution of a polishing table supporting the substrate;
producing the measurement spectrums from the detected light in the detection regions; and
selecting one of the measurement spectrums.

4. The polishing method as claimed in claim 1, wherein the measurement spectrum represents an intensity of the reflected light over a predetermined wavelength range.

5. The polishing method as claimed in claim 1, wherein performing the Fourier transform operation on the skew spectrum to calculate the thickness of the layer includes:
performing the Fourier transform operation on the skew spectrum to obtain a Fourier transform spectrum; and
determining the thickness of the layer based on a peak position of the Fourier transform spectrum.

6. The polishing method as claimed in claim 5, wherein the Fourier transform spectrum represents an intensity of the light according to the thickness.

7. The polishing method as claimed in claim 1, further comprising obtaining the golden spectrum from a surface of a substrate having a layer with the target thickness using a measuring instrument.

8. The polishing method as claimed in claim 1, wherein:
polishing the substrate includes rotating a polishing table supporting the substrate, and
obtaining the measurement spectrum from the polished surface of the substrate includes obtaining a plurality of the measurement spectrums corresponding to a plurality of the revolutions of the polishing table.

9. The polishing method as claimed in claim 8, wherein polishing the substrate includes rotating the polishing table until the calculated thickness reaches the target thickness.

10. The polishing method as claimed in claim 1, further comprising determining a polishing end point based on the calculated thickness.

11. A polishing method, comprising:
obtaining a golden spectrum from a surface of a substrate having a layer with a target thickness;
polishing a layer on a substrate to form a polished surface formed thereon;
obtaining a measurement spectrum by detecting light reflected from the polished surface of the substrate;
obtaining a skew spectrum between the golden spectrum and the measurement spectrum; and
performing a Fourier transform operation on the skew spectrum to calculate a thickness of the layer.

12. The polishing method as claimed in claim 11, wherein obtaining the measurement spectrum includes:
detecting the light reflected from the surface of the substrate during each one revolution of a polishing table supporting the substrate; and
producing the measurement spectrum from the detected light.

13. The polishing method as claimed in claim 11, wherein performing the Fourier transform operation on the skew spectrum to calculate the thickness of the layer includes
performing the Fourier transform operation on the skew spectrum to obtain a Fourier transform spectrum; and
determining the thickness of the layer based on a peak position of the Fourier transform spectrum.

14. The polishing method as claimed in claim 11, wherein:
polishing the substrate includes rotating a polishing table until the calculated thickness reaches the target thickness, and
obtaining the measurement spectrum from the polished surface of the substrate includes obtaining a plurality of the measurement spectrums corresponding to a plurality of the revolutions of the polishing table.

15. The polishing method as claimed in claim 11, further comprising determining a polishing end point based on the calculated thickness.

16. A method of manufacturing a substrate, the method comprising:
forming a layer on the substrate; and
polishing a first surface of the layer on the substrate, wherein polishing the layer on the substrate includes
obtaining a measurement spectrum by detecting light reflected from the first surface of the layer;
obtaining a skew spectrum between a golden spectrum for a target thickness and the measurement spectrum; and
performing a Fourier transform operation on the skew spectrum to calculate a thickness of the layer.

17. The method as claimed in claim 16, wherein:
polishing the first surface includes buffing the first surface, and
obtaining the measurement spectrum, obtaining a skew spectrum between a golden spectrum for a target thickness and the measurement spectrum, and performing the Fourier transform operation occur during buffing.

18. The method as claimed in claim 17, wherein, before buffing, polishing exposes two different materials on the first surface.

19. The method as claimed in claim 16, wherein:
polishing includes at least two different polishing processes, and
obtaining the measurement spectrum, obtaining a skew spectrum between a golden spectrum for a target thickness and the measurement spectrum, and performing the Fourier transform operation occur during a final process of at least two different polishing processes.

20. The method as claimed in claim 19, further comprising determining a polishing end point based on the calculated thickness.
